(19) United States
(12) Patent Application Publication
(10) Pub. No.: US 2023/0317865 A1
(43) Pub. Date: Oct. 5, 2023

(54) TEXTURED GLASS FOR PHOTOVOLTAIC INSTALLATION

(71) Applicant: SAINT-GOBAIN GLASS FRANCE, COURBEVOIE (FR)

(72) Inventors: Emmanuel MIMOUN, BOULOGNE-BILLANCOURT (FR); Michele SCHIAVONI, PARIS (FR); Patrick GAYOUT, VILLEMOMBLE (FR)

(21) Appl. No.: 18/247,043

(22) PCT Filed: Oct. 8, 2021
(86) PCT No.: PCT/FR2021/051752

§ 371 Date: Mar. 28, 2023

(30) Foreign Application Priority Data
Oct. 8, 2020 (FR) FR2010295

(51) Int. Cl. H01L 31/0236; H01L 31/0392; H01L 31/048

(52) U.S. Cl. CPC H01L 31/02366; H01L 31/0392; H01L 31/048

(57) ABSTRACT

A translucent glass pane-type substrate, adapted to serve as a cover element for a photovoltaic cell, the substrate including at least one textured surface intended to be oriented towards the outside of a building and wherein for any texture orientation, the fraction of local surfaces having said texture orientation is less than or equal to 2×10⁻⁴ of a given sampling surface

The present invention relates to a translucent glass pane-type substrate, adapted to cover a photovoltaic cell.

The invention additionally relates to a photovoltaic installation integrating such a substrate and being adapted to be building integrated, to be facade and/or roof mounted, for the purpose of producing electricity.

Making buildings self-sufficient energy-wise and reducing their ecological footprint is one of the main challenges when developing towns and in modern construction. Photovoltaic panels (PV panels) are an important source of renewable energy. Nevertheless, their use in buildings is often limited due to the difficulties encountered in integrating such PV panels in buildings, from both an aesthetic and structural point of view. Thus, the appearance of conventional photovoltaic cells, provided by the dark blue color of silicon and the silver electrical contacts on the surface, is not considered attractive for town facades and roofs. In this respect, building integrated photovoltaics (BIPV) comprises the use of structural, aesthetic and architectural solutions to ensure a harmonious integration of photovoltaic cells in different types of buildings.

An avenue that has been explored to radically modify the appearance of a photovoltaic panel without changing the active silicon medium consists of modifying the cover element thereof, i.e., the optical system, often made of glass and referred to as coverglass, which is arranged above the photovoltaic cell such that it covers the latter, as viewed from the outside of the building.

The implementation of such a cover element enables the photovoltaic cell to be mechanically and chemically protected, while preserving satisfactory light transmission performance. It is indeed important for such a cover element to have an effective light transmission, such that a significant part of the incident rays is refracted and transmitted through the cover element. In photovoltaic cells conventionally having a very high optical index, the glass further enables the performance thereof to be increased by means of gradient-index optics.

A strategy for increasing the energy conversion efficiency of a photovoltaic cell consists of improving the transmission properties of the cover element particularly by limiting the reflection of incident solar radiation. To this effect, texturing is known of at least the face of the cover element opposite from the photovoltaic cell by providing it with a plurality of embossed geometrics designs, either concave or convex with respect to a general plane of this face. In this invention, the general plane of the substrate is the plane containing the points of the textured surface that do not belong to the designs or, in the case of connected designs, the connecting points between the designs. Thus, implementing regular pyramid- or cone-shaped designs is known, or also designs having a preferred longitudinal direction, such as grooves or ribs.

A major disadvantage of standard external glazings is that they can cause risks of glare, with ramifications in terms of safety, for example when vehicle headlights reflect on the glazed facades of buildings. This problem particularly arises for glazed facades close to airports. It is in fact essential to remove all risk of glare for pilots approaching the terminals.

It is established that a glare is visible to the human eye due to a luminous intensity greater than 10000 candelas per square meter (cd/m2). This glare becomes particularly troublesome above a value of 20000 cd/m2.

The texturing of the external face of the glazing enables the risk of glare to be reduced, by creating an at least partially diffuse reflection of the incident rays. Despite this improvement, and as detailed in the following disclosure, the textured surfaces known in the state of the art, at least under a certain viewing angle, tend to create a luminous intensity greater than this threshold value of 20000 cd/m2.

The proposed technique enables the aforementioned disadvantages to be addressed and is more particularly related to, in at least one embodiment, a translucent glass pane-type substrate, adapted to serve as a cover element for a photovoltaic cell, said substrate comprising at least one textured surface intended to be oriented towards the outside of a building and characterized in that for any texture orientation (θ; φ), the fraction of local surfaces having said texture orientation (θ; φ) is less than or equal to 2×10⁻⁴ of a given sampling surface, or preferably 1×10⁻⁴, more preferably 5×10⁻⁵.

In the present text, the glass pane-type substrate is said to be translucent insofar as it gives rise to a diffuse transmission of an incident radiation. A textured surface is a surface for which the surface irregularities vary at a scale greater than the wavelength of the radiation incident on the surface.

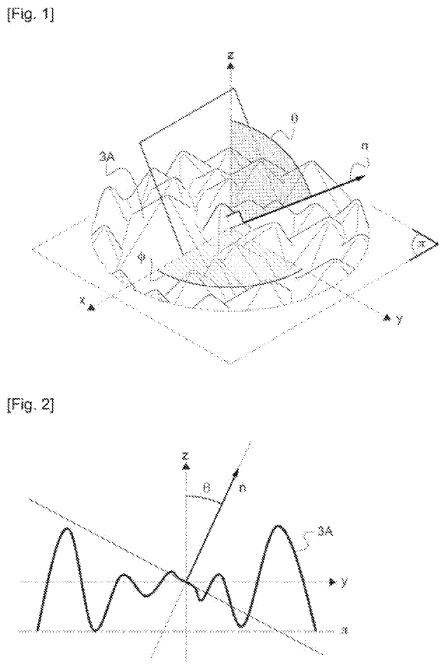

Throughout the text, the texture orientation at a point of the surface (local) of the substrate designates the orientation (θ; φ) of the local normal vector (n), i.e., the vector (n) that is normal to the plane tangent to this local textured surface. Typically, this orientation is defined with respect to the general plane of the substrate (π). FIG. 1 is a schematic and three-dimensional depiction of such a local normal vector (n), at a point (P) of the textured surface. The local normal vector (n) can particularly be designated by the spherical coordinates thereof, whereby θ (theta) is the angle formed by this vector with respect to the normal to the general plane (π) of the substrate, and φ (phi) is the angle formed with the x-axis in the general plane (π) of the substrate. FIG. 2 is a section of FIG. 1A according to the plane comprising the vertical z-axis and the local normal vector (n).

Throughout the whole text, two local surfaces are referred to as “having the same texture orientation (θ; φ)” if the two corresponding local normal vectors form an angle less than 0.5°. The fraction of local surfaces having the same texture orientation (θ; φ) thus designates an assembly wherein each local surface has a normal vector forming an angle less than 0.5° with the normal vectors of all the other local surfaces comprised in this same assembly.

The measurement of the texture orientation (θ; φ) of a local surface is carried out based on a measurement of the local height of the surface, according to a 20 micrometer dot grid, in two orthogonal directions of the space hereinafter referred to as x and y. This measurement is then computer processed in order to eliminate the high-pitch waves (in general greater than 10 mm, or even greater than 15 mm). Based on this two-dimensional height matrix, the local texture orientation according to two directions x and y is obtained by differentiating two consecutive points of the grid in the direction of interest, and dividing by the pitch of the grid. A two-dimensional vector is thus obtained at each point of the grid surface, in the x y space. It is then more practical to convert it in space (theta, phi) by using formulae known in the state of the art. By denoting n as the vector, and nₓ and n_{y} as the previously calculated components, theta and phi can be obtained as theta=acos(1/sqrt(1+nₓ²+n_{y}²)) and phi=atan 2(−n_{y}/sqrt(nₓ²+n_{y}²),−nₓ/sqrt(nₓ²+n_{y}²)). A theta angle and a phi angle is thus obtained for each point of the meshed surface.

The invention is based on a novel and inventive concept consisting of implementing a substrate the texturing of which is such that no texture orientation predominates in a manner visible to the human eye, particularly in terms of glare. Specifically, this results from the implementation of a texture orientation (θ; φ) distribution such that no texture orientation value is represented beyond a predetermined threshold, this threshold corresponding to the requirements set in terms of reducing the risks of glare.

Surprisingly, it has been noted by the inventors that glare resulting from the reflection of solar rays on a textured surface does not depend on the slope values measured locally or the local orientation (θ; φ) of the texture thereof. Regardless of this texture orientation at the local scale, there is still an area of concentration of the reflected rays to, at the macroscopic scale, create a risk of glare.

By targeting the distribution of the local texture orientations on a large textured surface, the invention thus enables the areas of concentration of the locally reflected rays, at the macroscopic scale, to be sufficiently dispersed in order to limit the risks of glare in all directions.

With this in mind, and as detailed in the disclosure, a research program was launched by the inventors in order to determine a plurality of threshold values of the fraction of local surfaces having a given texture orientation, above which a risk of glare is identified as visible to the human eye and/or at least troublesome.

This resulted in the selection of 2×10⁻⁴ as the threshold value of the fraction of local surfaces having any orientation below which a particular discomfort related to glare is not noted, regardless of the position of the observer and that of the light source.

According to a particular embodiment, said sampling surface is greater than or equal to 5×5 cm². The sampling surface being a subcomponent of the textured surface (3A), the latter thus incidentally being greater than or equal to 5×5 cm2.

According to a particular embodiment, the fraction of local surfaces having said texture orientation (θ; φ) is less than or equal to 1×10⁻⁴, preferably less than or equal to 5×10⁻⁵.

The value of 1×10⁻⁴ is identified as the threshold value of the fraction of local surfaces having any orientation below which the glare phenomenon is not visible to the human eye, regardless of the position of the observer and that of the light source. The value of 5×10⁻⁵ is identified as the threshold value of the fraction of local surfaces having any orientation below which the glare phenomenon is not visible to the human eye, or to another target having an increased sensitivity to luminance, regardless of the position of the observer and that of the light source.

According to a particular embodiment, the maximum height (Sz) of said textured surface (3A) is less than 1.1 mm.

The maximum height (Sz) of a textured surface is defined by the ISO standard 25178 and corresponds to the difference between the lowest point and highest point thereof.

As indicated in the text, the ability of a substrate according to the invention to limit the risks of glare does not depend on the maximum height Sz of the surface texture thereof, but rather on the distribution of the texture orientations on the assembly of the considered surface. Provided that the criteria established on this texture orientation distribution is respected, it is thus possible to implement the invention for a texturing with a very shallow depth (height Sz), particularly a texturing the maximum height Sz of which is less than 1.1 mm.

According to a particular embodiment, the thickness of said substrate is less than or equal to 4.0 mm, preferably less than or equal to 3.6 mm, preferably less than or equal to 3.4 mm, preferably less than or equal to 3.2 mm.

As described in the present text, a texturing according to the invention has the benefit of being able to be implemented with a shallow, or even very shallow design depth (height). It is thus possible to texture a substrate the thickness of which is also small (4.0 mm), or even very small (3.2 mm), without unacceptably impacting the physical properties thereof, particularly the mechanical strength characteristics thereof.

According to a particular embodiment, at all points of said sample surface, the radius of curvature is greater than 300 micrometers for a curvature oriented towards the outside of the substrate, and greater than 200 micrometers for a curvature oriented towards the inside of the substrate.

In the present text, curvature “oriented towards the outside of the substrate” refers to a negative concave curvature, and curvature “oriented towards the inside of the substrate” refers to a positive convex curvature.

In practice, the curvature is obtained by deriving the grid surface in the same way as before, but to the order of 2. Three matrices are thus obtained depending on whether we derive twice in the x direction, once according to x and once according to y, and twice according to y. There is thus a vector with three components Cₓₓ, C_{xy} and C_{yy}, and the local mean curvature can be calculated at each point, and the corresponding radius of curvature is deduced therefrom, as well as the orientation of the curvature, inwardly or outwardly

According to a particular embodiment, the texture orientation (θ; φ) represented at the maximum has an angle θ (theta) equal to 0°.

As described in the present text, θ (theta) is the angle formed between the local normal vector and the normal to the general plane of the substrate. A null angle value θ thus designates a surface that, locally, is parallel to the general plane of the substrate.

According to a particular embodiment, the texture orientation (θ; φ) represented at the maximum has an angle θ (theta) equal to 45°.

According to a particular embodiment, at least 50% of the sampling surface has a texture orientation (θ; φ) the angle θ (theta) of which is greater than 30°.

Such textured surface enables the incident light to be trapped and thus increase the performance of the photovoltaic cell.

According to a particular embodiment, for all angles φ (phi), the distribution of texture orientations according to the angle θ (theta) is identical, or substantially identical.

The perception of reflections at the surface of the substrate is thus the same, or substantially the same (in terms of human perception), regardless of the orientation of the substrate according to the component φ (phi) thereof. The isotropic behavior of glazing is referred to here.

According to a particular embodiment, the textured surface (3A) is at least partially coated with an anti-reflective coating.

This anti-reflective coating may be of any type that makes it possible to reduce the reflection of radiation at the interface between the two optical media. It may be in the form of a refractive index layer comprised between the refractive index of air and the refractive index of the substrate, such as a layer deposited by a vacuum technique or a sol-gel porous layer. As a variant, the antireflective coating may be formed by a stack of thin layers having alternating lower and higher refractive indices, performing the role of an interference filter at the interface between the air and the substrate, or by a stack of thin layers having a continuous or stepped gradient of refractive indices between the refractive index of air and that of the substrate.

The presence of an anti-reflective coating thus enables the reflection phenomenon to be reduced at the level of the textured surface of the substrate.

The risks of reflection glare are thus reduced.

According to a particular embodiment, said textured surface substantially covers the entirety of at least one of the main faces of the glass pane-type substrate.

According to a particular embodiment, the surface intended to be oriented towards the photovoltaic cell, and opposite to said textured surface (3A), is smooth or textured.

According to a particular embodiment, the material comprising said textured surface is a mineral glass preferentially comprising iron oxide in a total weighted content (expressed in Fe2O3) of at most 0.030%, particularly of at most 0.020%, even 0.015%, and which is preferentially of the soda-lime-silica type with the following weight composition:
SiO2 50-75%
CaO 5-15%
MgO 0-10%
Na2O 10-20%
Al2O3 0-5%
K2O 0-5%.

The present features relate to glass of the extra clear type, and more particularly to glass matrices Diamant™ and Albarino™, marketed by Saint-Gobain. These glass substrates have the benefit of having a light transmission greater than 91.4%. They are thus differentiated from the so-called “clear” glass the light transmission of which is generally less than 90%. Throughout the text, the light transmission is measured in % according to the standard NF EN410-2011 (illuminant D65; 2° Observer) with a Lambda950™ spectrometer from Perkin Elmer. A glass with such composition thus has an excellent performance in light transmission, which makes it an ideal candidate to serve as a cover element for a photovoltaic cell.

Likewise, the invention relates to a manufacturing method of such a substrate by rolling using a textured print cylinder that preferably bears designs having a local slope greater than the local slope of said textured surface, preferably of at least 0.5°.

The slopes performed on a mineral glass by means of hot rolling, generally in a temperature range from 800 to 1300° C., reduce slightly during formation. As such, if an average slope with value Pm is desired at the level of the glass sheet, a print cylinder, the designs of which have an average slope of at least Pm+0.5°, or even at least Pm+1°, is preferably used. The bigger the design of texture, i.e., the bigger the lateral x and y dimensions, and the closer the effectively printed texture is to that of the cylinder and the less it is necessary to correct the designs of the cylinder.

The invention also relates to a photovoltaic installation adapted to be building-integrated, characterized in that it comprises a photovoltaic cell at least partially covered by such translucent substrate.

The invention also relates to the building, facade and/or roof mounting, of at least one such photovoltaic installation.

The invention also relates to the use of one such photovoltaic installation, preferably building mounted, for the production of electric energy.

Other features and advantages of the invention will become apparent upon reading the following description of particular embodiments, provided by way of simple illustrative and non-limiting examples, and from the attached figures, whereby:

FIG. 1 is a schematic depiction of the vector (n) normal to a local textured surface,

FIG. 2 is a sectional schematic view of FIG. 1 according to the plane containing the axis (z) normal to the general plane (π) of the substrate and the local normal vector (n),

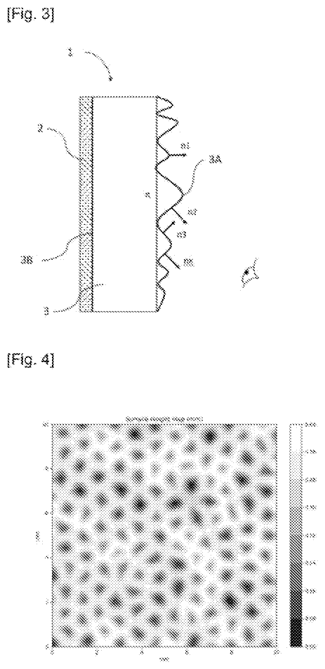

FIG. 3 is a schematic transverse section of a photovoltaic installation (1) adapted to be building-integrated,

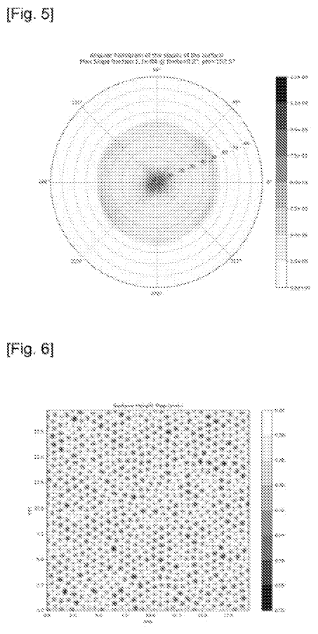

FIGS. 4 and 5 are respectively the map of the local heights and the angular histogram of the local texture orientations obtained after the implementation of a first test, according to a particular embodiment of the invention,

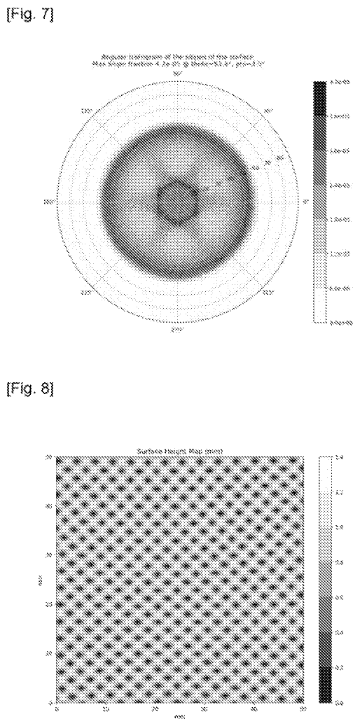

FIGS. 6 and 7 are respectively the map of the local heights and the angular histogram of the local texture orientations obtained after the implementation of a second test, according to a particular embodiment of the invention,

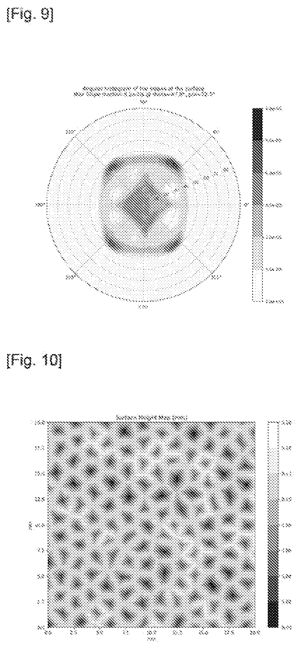

FIGS. 8 and 9 are respectively the map of the local heights and the angular histogram of the local texture orientations obtained after the implementation of a third test, according to a particular embodiment of the invention,

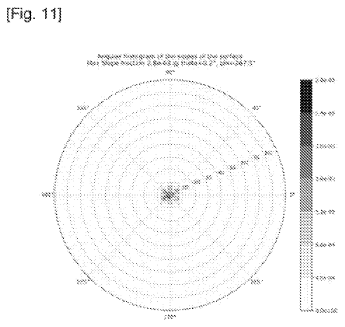

FIGS. 10 and 11 are respectively the map of the local heights and the angular histogram of the local texture orientations obtained after the implementation of a fourth test, according to an embodiment not covered by the invention.

The different features illustrated by the figures are not necessarily depicted at full scale, the focus being more on the depiction of the general operation of the invention. In the various figures, unless otherwise stated, the reference numbers that are the same represent similar or identical elements.

Several particular embodiments of the invention are presented below. It is understood that the present invention is not limited in any way by these particular embodiments and other embodiments can be implemented perfectly.

FIG. 3 illustrates, according to a sectional schematic view, a photovoltaic installation (1) adapted to be building-integrated. Such an installation (1) comprises a photovoltaic cell (2) covered by a transparent or translucent substrate (3) according to the invention. This photovoltaic cell benefits from the technical effects linked to the implementation of a textured substrate. Thus, the light rays impacting on the outer surface of the substrate (3) are only partially reflected and/or absorbed, particularly due to the advantageous surface texturing of the substrate, and due to the composition thereof with glass of the extra clear type.

Due to the diffuse reflection, a portion of the incident solar rays is thus reflected in a diffuse manner to the surface of the substrate, which enables limiting glare and the generation of hot points.

Due to the specular transmission, another portion of the incident rays is specularly refracted and transmitted through the substrate, which enables the energy losses to be limited, and thus maximize the exposure of the photovoltaic cell (2).

The implementation of such a substrate (3) thus enables satisfactory performance of light transmission to be obtained while limiting the risks of reflection glare.

Added to this is a light trapping effect at the level of the inner face of the substrate (3). Specifically, after passing through this substrate (3) a first time, a first portion of incident rays is absorbed by the photovoltaic cell (2), while a second portion is reflected towards the same substrate (3). A sub-portion of this reflected light is thus retro-reflected by the substrate (3) towards the photovoltaic cell (2), which enables the energy efficiency to be further improved, or in other words, to optimize the electrical energy production thereof.

FIG. 3 represents the angular components 6 (theta) of a plurality of local normal vectors (n1, n2, n3, nₓ) relating to different local surfaces of the textured surface (3A).

In order to assess the role played by the texture orientation (θ; φ) distribution on the reduction of the reflection luminance, a series of 3 (three) tests are computer simulated for a substrate (3) according to the invention. A final test is computer simulated for a substrate that does not conform to the distribution criteria set by the invention, by way of counterexample. These four tests are simulated under perfectly identical conditions, and only differ from one another in their texture orientation distribution.

For each test, a map of the local heights, as well as an angular histogram of the slopes of the surface are extracted and discussed. The map of the heights presents a graduated gray scale related to computer simulated heights on the sampling surface. The angular histogram of local texture orientations presents a gray scale related to the concentration of local surfaces presenting the orientation (θ; φ) given in the histogram, the concentric circles relate to the value of the angle θ (theta), increasing from the inside towards the outside of the histogram, while the values of the quadrant relate to the value of the angle φ (phi).

It must be noted that in practice, and in a non-limiting manner, the texture orientation (θ; φ) measurement of a local surface is carried out based on a measurement of the local height of the surface, according to a 20 micrometer (μm) dot grid at the most, in two orthogonal directions of the space hereinafter referred to as x and y. The high-pitch waves (in general greater than 10 mm, or even greater than 15 mm) are hereinafter eliminated by computer processing. Based on this two-dimensional height matrix, the local texture orientation according to two directions x and y is obtained by differentiating two consecutive points of the grid in the direction of interest, and dividing by the pitch of the grid. A two-dimensional vector is thus obtained at each point of the grid surface, in the x y space. It is then more practical to convert it in space (theta, phi) by using formulae known in the state of the art. By denoting n as the vector, and nₓ and n_{y} as the previously calculated components, theta and phi can be obtained as theta=acos(1/sqrt(1+nx²+ny²)) and phi=atan 2(−ny/sqrt(nx²+ny²),−nx/sqrt(nx²+ny²)). A theta angle and a phi angle is thus obtained for each point of the meshed surface.

FIGS. 4 and 5 are respectively the map of the local heights and the angular histogram of the local texture orientations (θ; φ) obtained after the implementation of the first test. According to this first test, the orientation (θ; φ) having the highest distribution or, in other words, the texture orientation (θ; φ) represented at the maximum, has an angle θ (theta) equal to 0°, although a sufficient amount of the surface has been deviated from this direction to provide the low luminance of the reflection of the sun in any direction. The most represented texture orientation (θ=0°; φ) only occupies 1×10⁻⁴ of the textured surface (3A), which experimentally leads to a luminance value of 4500 cd/m², experimentally observed for the sun entering at angles less than 30°. In practice, such a value is measure by means of a Minolta™ luminance meter on a day with full sunshine in June.

An orientation of the texture at θ=0° particularly favors the transmission of incident rays oriented according to a direction substantially orthogonal to the general plane of the substrate or in other words, the component θ (theta) of which is equal to or close to 0°. In practice, such a configuration is found in roof mountings of photovoltaic installation, which are preferred herein.

In addition, the angular histogram of the local texture orientations (θ; φ) (FIG. 5) shows a central symmetry as well as according to all the directions of φ (phi), which demonstrates the fact that for all angles φ (phi), the distribution of texture orientations according to the angle θ (theta) is identical. A textured surface according to this first test thus has an isotropic behavior.

FIGS. 6 and 7 are respectively the map of the local heights and the angular histogram of the local texture orientations (θ; φ) obtained after the implementation of the second test. According to this second test, a large portion of the surface (more than 50%) is maintained at high angular component texture orientations θ (about 50°). However, the distribution of these orientations is spread out according to the angles θ and φ, so that the most represented texture orientation only occupies 4×10⁻⁵ of the textured surface (3A). A luminance of 1500 cd/m² is obtained. This configuration is best adapted to being facade mounted for which the trapping effects of the light due to the presence of slopes with high angles θ are favored.

In addition, the angular histogram of the local texture orientations (θ; φ) (FIG. 7) shows a central symmetry as well as very small variations of the angle θ depending on the angle φ, not visible to the human eye. A textured surface according to this second test thus has a substantially isotropic behavior.

FIGS. 8 and 9 are respectively the map of the local heights and the angular histogram of the local texture orientations (θ; φ) obtained after the implementation of the third test. According to this third test, the implemented designs are pyramid-shaped with a square base and the orientation (θ; φ) having the highest distribution has an angle θ (theta) equal to 45°. The angular spread according to θ is less effective than according to the second test, with a fraction of 8.2×10⁻⁵ of the textured surface (3A) thus oriented, which experimentally leads to a maximum of 3500 cd/m2 experimentally observed for the sun entering at angles lower than 30. Therefore, this is far from the glare values that can cause discomfort to the human eye. It must be noted that such a texture, although it is less efficient in terms of reducing the risks of glare that a structure according to the second test, has the benefit of being easier to produce due to the regularity of the designs thereof (see FIG. 9).

FIGS. 10 and 11 are respectively the map of the local heights and the angular histogram of the local texture orientations (θ; φ) obtained after the implementation of the fourth test, not covered by the present invention.

According to this fourth test, by way of counterexample, the most represented texture orientation (θ=0°; φ) occupies 3×10⁻³ of the textured surface (3A) which, although appearing to be an insignificant fraction, leads to a luminance of 1.5×10⁵ cd/m², and thus a glare to be avoided.

The texturing of a translucent substrate according to the invention can be obtained by any known texturing method, for example by embossing the surface of the substrate previously heated to a temperature at which it is possible to deform it, in particular by rolling by means of a roller having on the surface thereof a complementary texturing of the texturing to be formed on the substrate, by engraving, or even by 3D printing, preferentially from a computer-generated texture.

According to a particular embodiment described for illustrative purposes, the texturing of a translucent substrate according to the invention is obtained by passing over an engraved roller, referred to as lower rolling roller, which is thus positioned facing the lower face of the glass on the production line. Typically, the lower (rolling) roller and the upper roller both have an outer diameter in the order of 200 mm. The upper roller may additionally have at the center thereof a concavity in the order of a millimeter.

In a manner known and controlled by a person skilled in the art, this lower roller is made of a steel (for example XC45F) the nature of which varies based on the method selected for the engraving of the surface. Thus, the engraving of the surface of the lower roller can be performed according to at least two alternative methods: engraving by laser ablation or the knurling of the surface. In the latter case, the knurl is made of a harder steel is itself engraved with the negative design of that of the rolling roller. In this case, the engraving is performed by the knurl compressing the material of the rolling roller. According to these methods, the engraving of the rolling roller is performed very accurately.

At first glance, the design engraved in the rolling roller corresponds to the negative of the texture desired for the surface of the rolled substrate. However, a person skilled in the art knows empirically how to anticipate the effects of the manufacturing method (relaxation of the textures during the cooling of the glass, stretching of the pattern substantially according to the axis of the production line, that is, the drawing axis) in order to determine the geometry of the design to be engraved in order to obtain, in fine, the target texture on the substrate.

Thus, preferentially, the height of the engraved design in the roller is increased, with respect to the target depth in the glass, by a factor depending on the lateral dimension of the design. The lateral dimension of the engraved design is, on the other hand, reduced according to the axis of the drawing, in order to obtain the lateral dimension desired for the texture of the substrate. Alternatively, or in a combined manner, the designs of the engraved roller have a local slope greater than the local slope of said textured surface, preferentially of at least 0.5°.

In a known and common manner for a person skilled in the art, other parameters of the production line are selected and adjusted to obtain a target texture, such as the temperature of the glass at the feeder (in the order of 1170° C.), the temperature of the cooling water of the rollers (37-38° C.), the temperature of the rolling temperature (comprised between 1100 and 1200° C.), the running speed of the substrate line. Thus, by way of example, a person skilled in the art knows how to adjust the rolling temperature depending on the thickness; a thinner glass needing to be hotter since it cools relatively quicker, while a thicker glass, on the contrary, must not be too hot so that it does not stick to the roller.

Generally, a person skilled in the art has the general knowledge to, based on a given objective of a texturing to be achieved, accurately obtain a dedicated engraving from the rolling roller, and adjust the parameters of the rolling method by rollers in order to obtain, by means of simple iterative tests, a substrate having the desired texturing.

1. A translucent glass pane-type substrate adapted to serve as a cover element for a photovoltaic cell, said substrate comprising at least one textured surface intended to be oriented towards an outside of a building and wherein for any texture orientation, a fraction of local surfaces having said texture orientation is less than or equal to 2×10⁻⁴ of a sampling surface greater than or equal to 5×5 cm².

2. The substrate according to claim 1, wherein a maximum height of said textured surface is less than 1.1 mm.

3. The substrate according to claim 1, wherein a thickness of said substrate is less than or equal to 4.0 mm.

4. The substrate according to claim 1, wherein at all points of said sampling surface, a radius of curvature is greater than 300 micrometers for a curvature oriented towards an outside of the substrate, and greater than 200 micrometers for a curvature oriented towards an inside of the substrate.

5. The substrate according to claim 1, wherein the texture orientation represented at a maximum has an angle θ equal to 0°.

6. The substrate according to claim 1, wherein the texture orientation represented at the maximum has an angle θ equal to 45°.

7. The substrate according to claim 1, wherein at least 50% of a sampling surface has a texture orientation an angle θ of which is greater than 30°.

8. The substrate according to claim 1, wherein for any angle φ, a distribution of the texture orientations according to the angle θ is identical.

9. The substrate according to claim 1, wherein the textured surface is at least partially coated with an anti-reflective coating.

10. The substrate according to claim 1, wherein said textured surface covers the entirety of at least one main face of the glass pane-type substrate.

11. The substrate according to claim 1, wherein a surface intended to be oriented towards an photovoltaic cell, and opposite to said textured surface, is smooth or textured.

12. The substrate according to claim 1, wherein a material comprising said textured surface is a mineral glass.

13. A manufacturing method of a substrate according to claim 1 comprising rolling a substrate using a textured print cylinder that bears designs having a local slope greater than the local slope of said textured surface.

14. A photovoltaic installation adapted to be integrated in a building, comprising a photovoltaic cell at least partially covered by a translucent substrate according to claim 1.

15. A method comprising at least one step for building, facade and/or roof mounting, of at least one photovoltaic installation according to claim 14.

16. A method comprising providing a photovoltaic installation according to claim 14 for the production of electric energy.

17. The method according to claim 13, wherein the local slope is at least 0.5°.
